(19) United States
(12) Patent Application Publication
(10) Pub. No.: US 2015/0348758 A1
(43) Pub. Date: Dec. 3, 2015

(54) IMPEDANCE MATCHING SLUG, IMPEDANCE MATCHING DEVICE, ELECTROMAGNETIC WAVE TRANSMISSION DEVICE, ELECTROMAGNETIC WAVE RADIATION DEVICE, AND PLASMA PROCESSING APPARATUS

(71) Applicant: TOKYO ELECTRON LIMITED, Tokyo (JP)

(72) Inventors: Hiroyuki MIYASHITA, Nirasaki City (JP); Taro IKEDA, Nirasaki City (JP); Yuki OSADA, Nirasaki City (JP); Tomohito KOMATSU, Nirasaki City (JP)

(21) Appl. No.: 14/716,175

(22) Filed: May 19, 2015

(30) Foreign Application Priority Data
Jun. 2, 2014 (JP) 2014-113728

(51) Int. Cl. H01J 37/32; H03H 7/38

(52) U.S. Cl. CPC H01J 37/32229; H03H 7/38; H01J 37/32311; H01J 37/3244; H01J 37/32458

(57) ABSTRACT

An impedance matching slug that performs an impedance matching process in a waveguide is axially movably interposed between an outer conductor and an inner conductor of the waveguide. The impedance matching slug includes: a cylindrical first part and a cylindrical second part which are coupled to each other, wherein each of the first part and the second part has an inner circumferential surface facing the inner conductor and an outer circumferential surface facing the outer conductor, wherein the second part is disposed in the outside of the first part in such a manner that the inner circumferential surface of the second part is in contact with the outer circumferential surface of the first part, wherein one of the first part and the second part is constituted by a conductor, and wherein the other of the first part and the second part is constituted by a dielectric.

### CROSS-REFERENCE TO RELATED APPLICATION

This application claims the benefit of Japanese Patent Application No. 2014-113728, filed on Jun. 2, 2014 in the Japan Patent Office, the disclosure of which is incorporated herein in its entirety by reference.

### TECHNICAL FIELD

The present disclosure relates to a slug for an impedance matching of a waveguide, an impedance matching device including the slug, an electromagnetic wave transmission device, an electromagnetic wave radiation device and a plasma processing apparatus.

### BACKGROUND

In a process of manufacturing a semiconductor device or a liquid crystal display device, a plasma processing apparatus such as a plasma etching apparatus or a plasma chemical vapor deposition (CVD) film forming apparatus is used to subject a substrate such as a semiconductor wafer or a glass substrate to a plasma process such as an etching process or a film forming process using plasma.

As one example of the plasma processing apparatus, there has been known an apparatus including an antenna for radiating a microwave into a chamber, a microwave supply source for generating the microwave, and a waveguide for transmitting the microwave generated by the microwave supply source to the antenna. In this plasma processing apparatus, the waveguide includes a cylindrical outer conductor and an inner conductor which is coaxial to the outer conductor and is installed inside the outer conductor, for example.

The plasma processing apparatus including the above-mentioned antenna, microwave supply source and waveguide is generally configured such that an output impedance of the microwave supply source and a characteristic impedance of the waveguide have the same value, for example, 50Ω. However, in general, an input impedance of the antenna is not equal to the characteristic impedance of the waveguide, and in addition, is varied depending on the configuration of the antenna and a type of a gas in the chamber. Therefore, an impedance matching process is necessary in order to supply sufficient power to the antenna.

In the related art, a slug tuner having a pair of slugs made of dielectric material has been known as a means for performing an impedance matching process. Each slug in the pair of slugs has a thick cylindrical shape and is interposed between an outer conductor and an inner conductor of a waveguide. The slugs in the pair of slugs are disposed at different positions in the axial direction and are axially movable independently of each other.

In the slug tuner, the input impedance of an antenna is converted by the pair of slugs into an impedance of a slug, which is disposed closer to a microwave supply source, seen from the microwave supply source side (hereinafter referred to as a post-conversion impedance). In the slug tuner, the post-conversion impedance can be changed by adjusting a distance between the antenna and a slug closer to the antenna and a distance between the pair of slugs. The impedance matching by the slug tuner is to make the post-conversion impedance equivalent to the output impedance of the microwave supply source by adjusting the above two distances.

The slug tuner is not limited to the above-described plasma processing apparatus but may be applied to a generalized system for transmitting an electromagnetic wave, which is supplied from an electromagnetic wave supply source, to a load through a waveguide having an outer conductor and an inner conductor. Hereinafter, a problem that may occur in a case where the output impedance of the electromagnetic wave supply source and the load input impedance are matched by the slug tuner in the generalized system will be described.

Whatever a value the load input impedance has, it does not mean that the conventional slug tuner can always set the post-conversion impedance to a predetermined value such as 50Ω. Hereinafter, a range of the load input impedance within which the post-conversion impedance can be set to the predetermined value is referred to as a matchable impedance range and a range of the load input impedance within which the post-conversion impedance cannot be set to the predetermined value is referred to as an unmatchable impedance range.

The unmatchable impedance range is an annular range on the Smith chart where the absolute value of a reflection coefficient is from a predetermined value close to 1 to 1. The unmatchable impedance range may be expressed using a voltage standing wave ratio. The voltage standing wave ratio is 1 when the absolute value of the reflection coefficient is 0, increases as the absolute value of the reflection coefficient increases, and is at infinity when the absolute value of the reflection coefficient is 1. Accordingly, the unmatchable impedance range may be referred to as an annular range on the Smith chart where the voltage standing wave ratio is from a predetermined value to infinity. The matchable impedance range is a range in the inside of the unmatchable impedance range.

In order to enable the impedance matching process by the slug tuner in a variety of situations, it is better that the matchable impedance range is as wide as possible.

As a related technique, a method of increasing the voltage standing wave ratio indicating a boundary of the matchable impedance range to 70 or so by forming a slug with high-purity alumina has been known. However, the expansion of the matchable impedance range by this method is limited, and thus there has been a desire for developing new technologies to further expand the matchable impedance range.

### SUMMARY

Some embodiments of the present disclosure provide an impedance matching slug which is capable of expanding a matchable load input impedance in comparison a slug entirely constituted by a dielectric, an impedance matching device including the slug, an electromagnetic wave transmission device, an electromagnetic wave radiation device and a plasma processing apparatus.

According to an embodiment of the present disclosure, there is provided an impedance matching slug that performs an impedance matching process between an output impedance of an electromagnetic wave supply source and an input impedance of a load, in a waveguide for transmitting an electromagnetic wave supplied from the electromagnetic wave supply source to the load, the waveguide including a cylindrical outer conductor and an inner conductor which is coaxial to the outer conductor and is installed inside the outer conductor, and the impedance matching slug being axially movably interposed between the outer conductor and the inner conductor. The impedance matching slug includes: a cylindrical first part and a cylindrical second part which are coupled to each other, wherein each of the first part and the second part has an inner circumferential surface facing the inner conductor and an outer circumferential surface facing the outer conductor. The second part is disposed in the outside of the first part in such a manner that the inner circumferential surface of the second part is in contact with the outer circumferential surface of the first part. One of the first part and the second part is constituted by a conductor, and the other of the first part and the second part is constituted by a dielectric.

According to another embodiments of the present disclosure, there is provided an impedance matching device that performs an impedance matching process between an output impedance of an electromagnetic wave supply source and an input impedance of a load, in a waveguide for transmitting an electromagnetic wave supplied from the electromagnetic wave supply source to the load, the waveguide including a cylindrical outer conductor and an inner conductor which is coaxial to the outer conductor and is installed inside the outer conductor. The impedance matching device includes: a first slug and a second slug which are axially movably interposed between the outer conductor and the inner conductor; and a driving mechanism that moves the first slug and the second slug in an axial direction, independently of each other. Each of the first slug and the second slug includes a cylindrical first part and a cylindrical second part which are coupled to each other. Each of the first part and the second part has an inner circumferential surface facing the inner conductor and an outer circumferential surface facing the outer conductor. The second part is disposed in the outside of the first part in such a manner that the inner circumferential surface of the second part is in contact with the outer circumferential surface of the first part. One of the first part and the second part is constituted by a conductor, and the other of the first part and the second part is constituted by a dielectric.

According to still another embodiments of the present disclosure, there is provided an electromagnetic wave transmission device including: a waveguide that transmits an electromagnetic wave supplied from an electromagnetic wave supply source to a load; and an impedance matching device that performs an impedance matching process between an output impedance of the electromagnetic wave supply source and an input impedance of the load. The waveguide includes a cylindrical outer conductor and an inner conductor which is coaxial to the outer conductor and is installed inside the outer conductor. The impedance matching device includes: a first slug and a second slug which are axially movably interposed between the outer conductor and the inner conductor; and a driving mechanism that moves the first slug and the second slug in an axial direction, independently of each other. Each of the first slug and the second slug includes a cylindrical first part and a cylindrical second part which are coupled to each other. Each of the first part and the second part has an inner circumferential surface facing the inner conductor and an outer circumferential surface facing the outer conductor. The second part is disposed in the outside of the first part in such a manner that the inner circumferential surface of the second part is in contact with the outer circumferential surface of the first part. One of the first part and the second part is constituted by a conductor, and the other of the first part and the second part is constituted by a dielectric.

According to still another embodiments of the present disclosure, there is provided an electromagnetic wave radiation device including: a waveguide that transmits an electromagnetic wave; an electromagnetic wave supply source that supplies the electromagnetic wave to the waveguide; an electromagnetic wave radiation antenna that radiates the electromagnetic wave transmitted by the waveguide; and an impedance matching device that performs an impedance matching process between an output impedance of the electromagnetic wave supply source and an input impedance of the electromagnetic wave radiation antenna. The waveguide includes a cylindrical outer conductor and an inner conductor which is coaxial to the outer conductor and is installed inside the outer conductor. The impedance matching device includes: a first slug and a second slug which are axially movably interposed between the outer conductor and the inner conductor; and a driving mechanism that moves the first slug and the second slug in an axial direction, independently of each other. Each of the first slug and the second slug includes a cylindrical first part and a cylindrical second part which are coupled to each other. Each of the first part and the second part has an inner circumferential surface facing the inner conductor and an outer circumferential surface facing the outer conductor. The second part is disposed in the outside of the first part in such a manner that the inner circumferential surface of the second part is in contact with the outer circumferential surface of the first part. One of the first part and the second part is constituted by a conductor, and the other of the first part and the second part is constituted by a dielectric.

According to still another embodiment of the present disclosure, there is provided a plasma processing apparatus including: a chamber that accommodates a substrate to be processed; a gas supply device that supplies a gas into the chamber; and an electromagnetic wave radiation device of some embodiments. The electromagnetic wave radiation antenna of the electromagnetic wave radiation device radiates an electromagnetic wave into the chamber. The gas supplied into the chamber is converted into plasma by the electromagnetic wave radiated into the chamber and the substrate is processed using the plasma.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view illustrating a schematic configuration of a plasma processing apparatus according to a first embodiment of the present disclosure.

FIG. 2 is a block diagram illustrating a configuration of an electromagnetic wave supply source in the first embodiment of the present disclosure.

FIG. 3 is a plan view illustrating the plasma processing apparatus shown in FIG. 1 when viewed from top.

FIG. 4 is a sectional view illustrating an electromagnetic wave transmission device according to the first embodiment.

FIG. 5 is a sectional view of the electromagnetic wave transmission device at a position indicated by line 5-5 in FIG. 4.

FIG. 6 is a sectional view of the electromagnetic wave transmission device at a position indicated by line 6-6 in FIG. 4.

FIG. 7 is a perspective view illustrating a slug according to the first embodiment of the present disclosure.

FIG. 8 is an explanatory view illustrating impedances at a plurality of positions within a waveguide in the first embodiment of the present disclosure.

FIG. 9 is an explanatory view illustrating the impedances at the plurality of positions shown in FIG. 8 on the Smith chart.

FIG. 10 is a sectional view illustrating a slug and an air layer within the waveguide in the first embodiment of the present disclosure.

FIG. 11 is a characteristic diagram illustrating a relationship between the radius of an outer circumferential surface of a first portion and an effective relative dielectric constant of a second portion in the slug shown in FIG. 10.

FIG. 12 is a characteristic diagram illustrating a relationship between the radius of the outer circumferential surface of the first portion and an optimal length of the slug in the slug shown in FIG. 10.

FIG. 13 is a characteristic diagram illustrating a relationship between the radius of the outer circumferential surface of the first portion and the characteristic impedance in the slug shown in FIG. 10.

FIG. 14 is a characteristic diagram illustrating a relationship between the radius of the outer circumferential surface of the first portion and a voltage standing wave ratio indicating a matchable load input impedance range in the slug shown in FIG. 10.

FIG. 15 is an explanatory view illustrating a matchable load input impedance range of a slug in a comparative example on the Smith chart.

FIG. 16 is an explanatory view illustrating the matchable load input impedance range of the slug according to the first embodiment of the present disclosure on the Smith chart.

FIG. 17 is a perspective view illustrating a slug according to a second embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

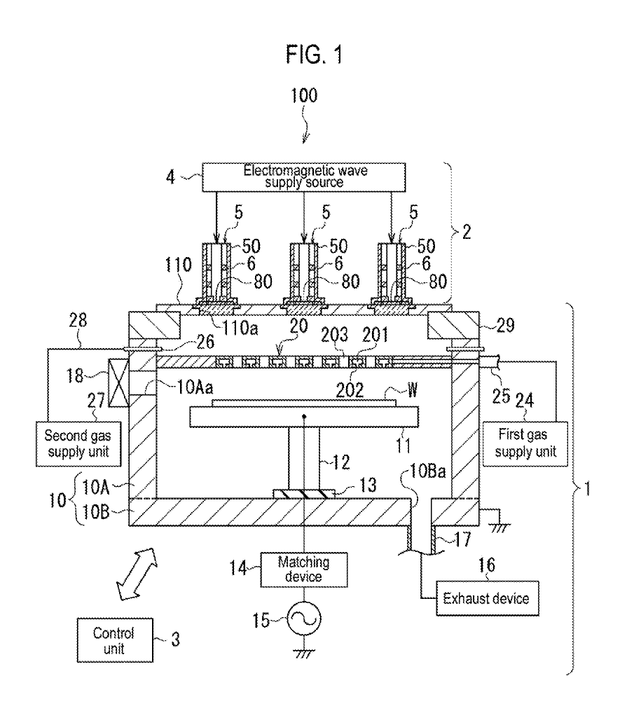

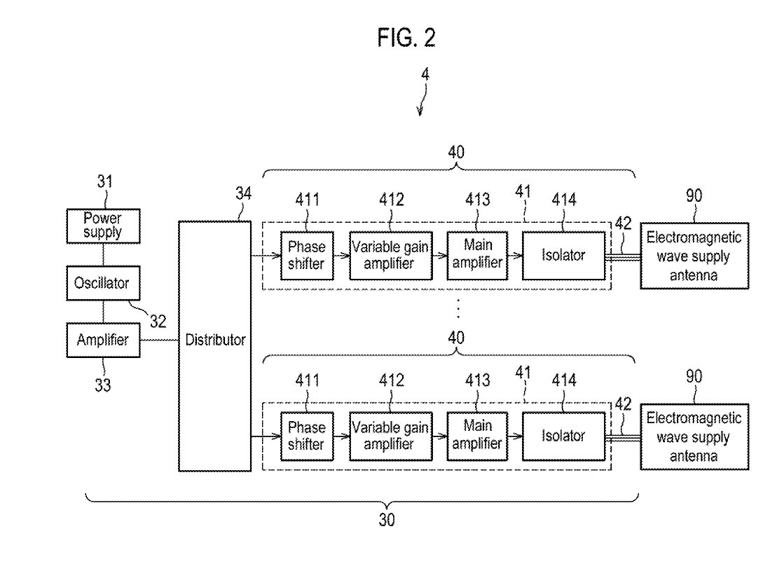

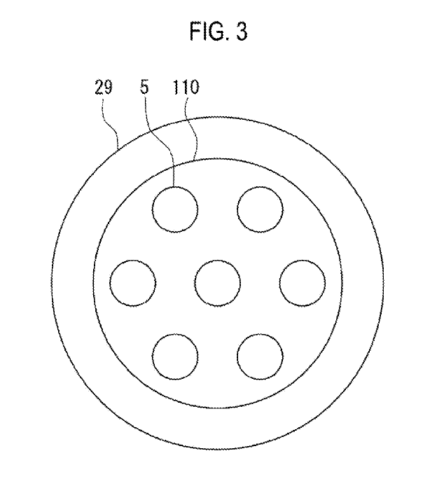

First, a schematic configuration of a plasma processing apparatus according to a first embodiment of the present disclosure will be described with reference to FIGS. 1 to 3. FIG. 1 is a sectional view illustrating a schematic configuration of a plasma processing apparatus according to the first embodiment. FIG. 2 is a block diagram illustrating a configuration of an electromagnetic wave supply source in the first embodiment. FIG. 3 is a plan view illustrating the plasma processing apparatus shown in FIG. 1 when viewed from top.

A plasma processing apparatus 100 according to the first embodiment is an apparatus for subjecting a substrate W such as a semiconductor wafer used to manufacture a semiconductor device to a predetermined plasma process such as deposition, diffusion, etching, ashing and the like. The plasma processing apparatus 100 includes a main body 1, an electromagnetic wave radiation device 2 according to the first embodiment, and a control unit 3 for controlling the main body 1 and the electromagnetic wave radiation device 2.

### <Main Body>

The main body 1 includes a chamber 10 in which a substrate W to be processed is accommodated. An electromagnetic wave, particularly, a microwave, is radiated into the chamber 10 by the electromagnetic wave radiation device 2. In addition, one or more types of gases are supplied into the chamber 10 by first and second gas supply units which will be described later. The gases supplied into the chamber 10 are converted into plasma by the electromagnetic wave radiated into the chamber 10. The plasma processing apparatus 100 processes the substrate W using this plasma.

The chamber 10 is made of metal, for example, aluminum or stainless steel. As shown in FIG. 1, the chamber 10 is grounded. The chamber 10 includes a cylindrical side wall 10A extending in the vertical direction in FIG. 1, and a plate-like bottom 10B blocking the lower end of the side wall 10A. In FIG. 1, a boundary between the side wall 10A and the bottom 10B is indicated by a broken line. The electromagnetic wave radiation device 2 radiates the electromagnetic wave from the top side of the side wall 10A into the chamber 10.

The main body 1 further includes a susceptor 11 on which the substrate W is mounted, a support member 12 for horizontally supporting the susceptor 11 in the chamber 10, and an insulating member 13 made of an insulating material. The support member 12 has, for example, a cylindrical shape extending in the vertical direction in FIG. 1. The susceptor 11 is fixed to the upper end portion of the support member 12. The lower end portion of the support member 12 is fixed to the center of the bottom of the chamber 10 via the insulating member 13. The susceptor 11 and the support member 12 are made of, for example, aluminum or the like having a surface subjected to an alumite treatment (anodization).

Although not shown, the susceptor 11 is provided with an electrostatic chuck for electrostatically adsorbing the substrate W, a temperature control mechanism for controlling a temperature of the substrate W, a gas passage for supplying a heat transfer gas for adjusting the temperature of the substrate W, and lift pins. The lift pins rise when the substrate W is transferred, and is configured to deliver the substrate W between the lift pins and a transfer chamber (not shown).

The main body 1 further includes a high frequency bias power supply 15 electrically connected to the susceptor 11, and a matching device 14 interposed between the susceptor 11 and the high frequency bias power supply 15. The high frequency bias power supply 15 supplies the susceptor 11 with bias power for attracting ions in plasma onto the substrate W.

The chamber 10 has an exhaust port 10Ba formed in the bottom 10B. The main body 1 further includes an exhaust device 16 and an exhaust pipe 17 connecting the exhaust port 10Ba of the chamber 10 and the exhaust device 16. The exhaust device 16 includes a vacuum pump for exhausting air in the chamber 10 and depressurizing the interior of the chamber 10 to a predetermined degree of vacuum.

The chamber 10 has a loading/unloading port 10Aa formed in the side wall 10A. The substrate W is loaded and unloaded through the loading/unloading port 10Aa. The main body 1 further includes a gate valve 18 for opening and closing between the loading/unloading port 10Aa and the transfer chamber (not shown).

The main body 1 further includes a shower plate 20 disposed above the susceptor 11 in the chamber 10. The shower plate 20 has a gas passage 201 formed therein in the form of a grid, a plurality of gas discharge holes 202 formed to be open from the gas passage 201 toward the top surface of the susceptor 11, and a plurality of through-holes 203 penetrating vertically through the shower plate 20. The plurality of though-holes 203 is formed to avoid the gas passage 201 and the plurality of gas discharge holes 202.

The main body 1 further includes a first gas supply unit 24 for supplying a processing gas used for plasma processing to the shower plate 20, and a pipe 25 connecting the first gas supply unit 24 and the gas passage 201 of the shower plate 20. The processing gas supplied into the gas passage 201 is discharged from the plurality of gas discharge holes 202 into the chamber 10.

The main body 1 further includes a plasma generation gas introducing member 26 installed in the side wall 10A of the chamber 10 above the shower plate 20, a second gas supply unit 27 for supplying a plasma generation gas used for plasma generation to the plasma generation gas introducing member 26, and a pipe 28 connecting the plasma generation gas introducing member 26 and the second gas supply unit 27. The plasma generation gas introducing member 26 has a plurality of gas discharge holes formed to be open toward the interior of the chamber 10 at predetermined intervals. The plasma generation gas supplied to the plasma generation gas introducing member 26 is discharged from the plurality of gas discharge holes into the chamber 10,

Although it is illustrated in the first embodiment that the processing gas and the plasma generation gas are supplied from the respective separate gas supply units, these gases may be supplied from the same gas supply unit.

The main body 1 further includes an annular support ring 29 connected to the upper end of the side wall 10A of the chamber 10, and a ceiling plate 110 supported by the support ring 29. A space between the support ring 29 and the ceiling plate 110 is air-tightly sealed. The ceiling plate 110 has a plurality of through-holes 110a penetrating vertically through the ceiling plate 110. The plurality of through-holes 110a is blocked by a dielectric member which will be described later. The support ring 29 and the ceiling plate 110 are made of, for example, the same material as the chamber 10.

### <Electromagnetic Wave Radiation Device>

The electromagnetic wave radiation device 2 according to the first embodiment includes a plurality of electromagnetic wave transmission devices according to the first embodiment and is configured to radiate a plurality of electromagnetic waves into the chamber 10. Specifically, the electromagnetic wave radiation device 2 includes an electromagnetic wave supply source 4, a plurality of electromagnetic wave transmission devices 5 and a plurality of electromagnetic wave radiation antennas 80. As shown in FIG. 1, the plurality of electromagnetic wave transmission devices 5 is disposed on the ceiling plate 110. The number of electromagnetic wave radiation antennas 80 is equal to the number of electromagnetic wave transmission devices 5. The plurality of electromagnetic wave radiation antennas 80 is disposed below the corresponding electromagnetic wave transmission devices 5 such that the antennas 80 can radiate the electromagnetic wave into the chamber 10. The plurality of through-holes 110a of the ceiling plate 110 is formed at positions corresponding to the plurality of electromagnetic wave radiation antennas 80.

FIG. 3 schematically shows arrangement of the plurality of electromagnetic wave transmission devices 5 on the ceiling plate 110. In the example shown in FIG. 3, the ceiling plate 110 has a circular shape when viewed from top. In this example, when viewed from top, the plurality of electromagnetic wave transmission devices 5 includes one electromagnetic wave transmission device 5 disposed in the center of the ceiling plate 110, and six electromagnetic wave transmission devices 5 disposed on the concentric circumference of the ceiling plate 110. Although not shown, the plurality of electromagnetic wave radiation antennas 80 is disposed at positions corresponding to the above-mentioned seven electromagnetic wave transmission devices 5.

Each of the plurality of electromagnetic wave transmission devices 5 includes a waveguide 50 and an impedance matching device 6 according to the first embodiment. The electromagnetic wave supply source 4 supplies an electromagnetic wave to the waveguide 50 of each of the plurality of electromagnetic wave transmission devices 5. The waveguide 50 serves to transmit the electromagnetic wave, which is supplied from the electromagnetic wave supply source 4, to a load. For the waveguide 50, the impedance matching device 6 is provided to match the output impedance of the electromagnetic wave supply source 4 with the input impedance of the load. In the first embodiment, the electromagnetic wave supplied from the electromagnetic wave supply source 4 is transmitted to the electromagnetic wave radiation antennas 80 serving as the load by the waveguide 50. The output impedance of the electromagnetic wave supply source 4 and the input impedance of the electromagnetic wave radiation antennas 80 are matched by the impedance matching device 6. The electromagnetic wave radiation antennas 80 radiate the electromagnetic wave, which is transmitted by the waveguide 50, into the chamber 10. The configuration of the electromagnetic wave transmission devices 5 will be described in more detail later.

### <Electromagnetic Wave Supply Source>

As shown in FIG. 2, the electromagnetic wave supply source 4 includes a plurality of electromagnetic wave supply antennas 90 and a power feeding part 30. The number of electromagnetic wave supply antennas 90 is equal to at least the number of electromagnetic wave transmission devices 5. Each of the plurality of electromagnetic wave supply antennas 90 generates an electromagnetic wave to be supplied to the waveguide 50 of the corresponding electromagnetic wave transmission device 5. The power feeding part 30 feeds power, which is used to generate the electromagnetic wave, to the plurality of electromagnetic wave supply antennas 90.

As shown in FIG. 2, the power feeding part 30 includes a power supply 31, an oscillator 32, an amplifier 33, a distributor 34, and a plurality of power supply paths 40 interposed between the distributor 34 and the plurality of electromagnetic wave supply antennas 90. The oscillator 32 is supplied with the power from the power supply 31 and outputs a high frequency power having a predetermined frequency range of, for example, a range of 700 MHz to 3 GHz. An example of the oscillator 32 may include a phase-locked loop (PLL) circuit. The amplifier 33 amplifies the high frequency power output from the oscillator 32. The distributor 34 distributes the high frequency power amplified by the amplifier 33 over the plurality of power supply paths 40. The number of power supply paths 40 is equal to the number of electromagnetic wave supply antennas 90.

Each of the plurality of power supply paths 40 includes an amplifier part 41 for amplifying the high frequency power distributed by the distributor 34, and a coaxial line 42 for supplying the amplified high frequency power to the corresponding electromagnetic wave supply antenna 90. The amplifier part 41 includes a phase shifter 411, a variable gain amplifier 412, a main amplifier 413 and an isolator 414. The phase shifter 411 adjusts the phase of the high frequency power distributed by the distributor 34. The variable gain amplifier 412 adjusts a level of the high frequency power input to the main amplifier 413. The phase and level of the high frequency power may be varied for each of the power supply paths 40. The main amplifier 413 amplifies the high frequency power with the adjusted phase and level. The isolator 414 is constituted by a circulator and a dummy load. The circulator guides the high frequency power, which is reflected by the electromagnetic wave supply antenna 90 toward the main amplifier 413, to the dummy load which then converts the guided high frequency power into heat.

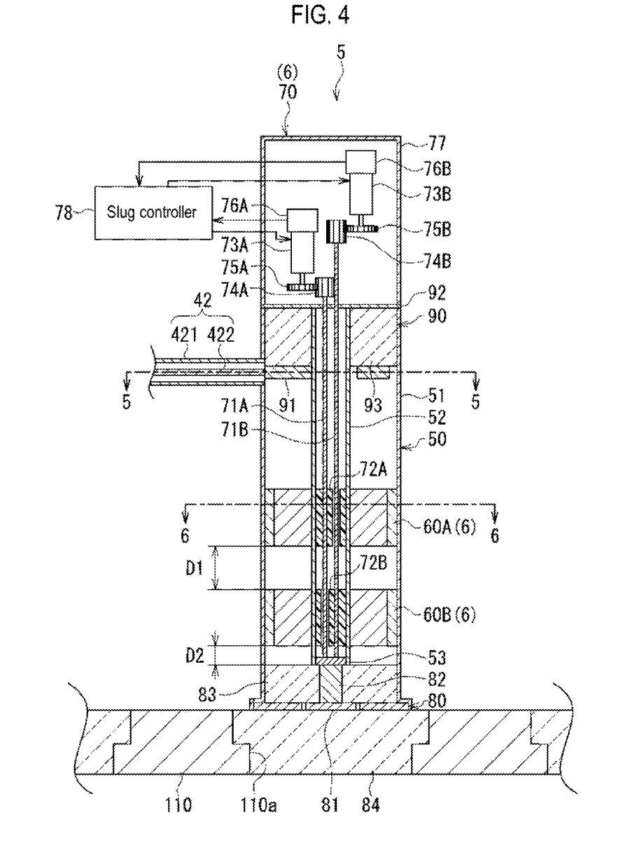

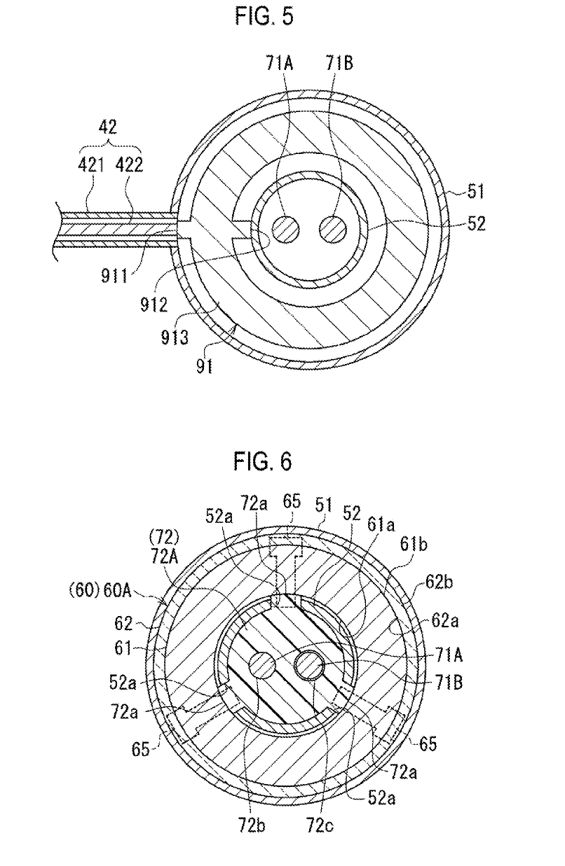

The coaxial line 42 includes a cylindrical outer conductor 421 and an inner conductor 422 which is coaxial to the outer conductor 421 and is installed inside the outer conductor 421. The outer conductor 421 and the inner conductor 422 are shown in FIGS. 4 and 5 which will be described below.

### <Electromagnetic Wave Transmission Device>

Next, the configuration of the electromagnetic wave transmission device 5 will be described in more detail with reference to FIGS. 4 to 6. FIG. 4 is a sectional view illustrating the electromagnetic wave transmission device 5 according to the first embodiment. FIG. 5 is a sectional view of the electromagnetic wave transmission device 5 at a position indicated by line 5-5 in FIG. 4. FIG. 6 is a sectional view of the electromagnetic wave transmission device 5 at a position indicated by line 6-6 in FIG. 4.

As described above, the electromagnetic wave transmission device 5 includes the waveguide 50 and the impedance matching device 6. The waveguide 50 includes a cylindrical outer conductor 51 and an inner conductor 52 which is coaxial to the outer conductor 51 and is installed inside the outer conductor 51. In the first embodiment, the outer conductor 51 has a cylindrical shape extending vertically in FIG. 4. The inner conductor 52 also has a cylindrical shape extending vertically in FIG. 4. The waveguide 50 has a bottom plate 53 which is made of a conductive material and is fixed to the lower end portion of the inner conductor 52, blocking the inner conductor. The lower end portion of the inner conductor 52 and the bottom plate 53 are disposed above the lower end portion of the outer conductor 51.

The electromagnetic wave radiation antenna 80 is disposed in the lower part of the waveguide 50. The electromagnetic wave radiation antenna 80 includes a plate-like antenna body 81 connected to the lower end portion of the outer conductor 51, blocking the outer conductor 51, a columnar member 82 which is made of a conductive material and connects the bottom plate 53 and the antenna body 81, a retardation member 83 made of a dielectric material, and a dielectric member 84 made of a dielectric material. A plurality of slots penetrating vertically through the antenna body 81 is formed in the antenna body 81.

The retardation member 83 is disposed on the antenna body 81 and has a through-hole penetrating vertically through the center of the retardation member 83 when viewed from top. The columnar member 82 is disposed within the through-hole of the retardation member 83. The retardation member 83 has the function to shortening the effective wavelength of an electromagnetic wave and the function to adjust the phase of the electromagnetic wave. The dielectric member 84 is disposed below the antenna body 81 and is fixed to the through-hole 110a of the ceiling plate 110, blocking the through-hole 110a. In the example shown in FIG. 4, the dielectric member 84 has an upper portion and a lower portion. The sectional area of the upper portion perpendicular to the central axis of the dielectric member 84 is larger than the sectional area of the lower portion perpendicular to the central axis of the dielectric member 84. The retardation member 83 and the dielectric member 84 may be made of, for example, quartz, ceramics, a fluorine-based resin such as polytetrafluoroethylene (PTFE) or the like, or a polyimide-based resin.

The electromagnetic wave supply antenna 90 is installed on the top of the waveguide 50. The electromagnetic wave supply antenna 90 includes an antenna body 91 interposed between the outer conductor 51 and the inner conductor 52, a reflection plate 92 connected to the upper end portion of each of the outer conductor 51 and the inner conductor 52, blocking the outer conductor 51 and the inner conductor 52, and a retardation member 93 which is made of dielectric material and is interposed between the antenna body 91 and the reflection plate 92. The retardation member 93 has the function to shorten the effective wavelength of an electromagnetic wave. The retardation member 93 may be made of, for example, a fluorine-based resin such as polytetrafluoroethylene (PTFE) or the like. If the frequency of the high frequency power supplied to the electromagnetic wave supply antenna 90 is relatively high (for example, 2.4 GHz), the retardation member 93 may not be provided.

As shown in FIG. 5, the antenna body 91 includes a first pole 911, a second pole 912 and a reflection portion 913. The first pole 911 is connected to the inner conductor 422 of the coaxial line 42. The second pole 912 is connected to the inner conductor 52 of the waveguide 50. The reflection portion 913 has a ring-like shape extending along the outer circumference of the inner conductor 52 at predetermined distances from the outer conductor 51 and the inner conductor 52 of the waveguide 50.

A distance between the antenna body 91 and the reflection plate 92 may be set, in some embodiments, to a distance at which a standing wave is generated by a portion of the electromagnetic wave radiated from the antenna body 91 and a reflected wave reflected by the reflection plate 92. Specifically, assuming that a wavelength (effective wavelength) of the electromagnetic wave between the antenna body 91 and the reflection plate 92 is λe, the distance between antenna body 91 and the reflection plate 92 may be set to (2n+1) λe/4 (n is an integer equal to or higher than zero).

### <Impedance Matching Device>

The impedance matching device 6 includes a first slug 60A and a second slug 60B which are movably interposed between the outer conductor 51 and the inner conductor 52 in an axial direction. The term “axial direction” used herein refers to a direction of the central axis common to the outer conductor 51 and the inner conductor 52. The first slug 60A and the second slug 60B have the same configuration. Hereinafter, in cases where the first slug 60A and the second slug 60B need not to be distinguished from each other, the first and second slugs 60A and 60B are simply referred to as a slug 60. The slug 60 is interposed between the electromagnetic wave supply antenna 90 and the electromagnetic wave radiation antenna 80 in order to match the output impedance of the electromagnetic wave supply antenna 90 of the electromagnetic wave supply source 4 and the input impedance of the electromagnetic wave radiation antenna 80 serving as a load. The slug 60 corresponds to the impedance matching slug recited in the present disclosure.

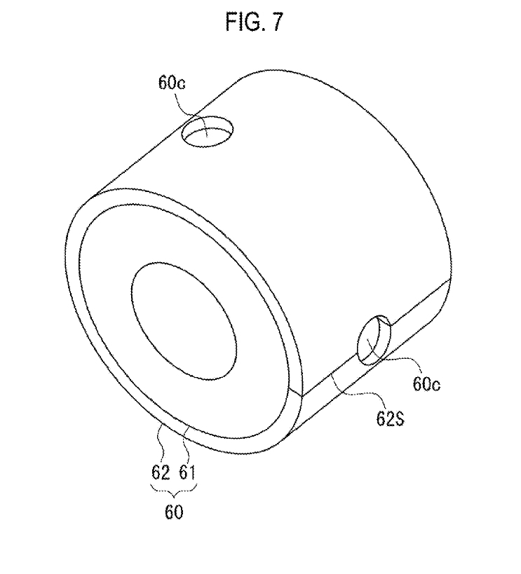

The configuration of the slug 60 will be described below with reference to FIGS. 6 and 7. FIG. 7 is a perspective view illustrating the slug 60. As shown in FIGS. 6 and 7, the slug 60 includes a cylindrical first part 61 and a cylindrical second part 62 which are coupled to each other. Each of the first part 61 and the second part 62 has an inner circumferential surface facing the inner conductor 52 and an outer circumferential surface facing the outer conductor 51. Hereinafter, the inner circumferential surface of the first part 61 is denoted by reference numeral 61a and the outer circumferential surface of the first part 61 is denoted by reference numeral 61b. The inner circumferential surface of the second part 62 is denoted by reference numeral 62a and the outer circumferential surface of the second part 62 is denoted by reference numeral 62b. The second part 62 is disposed in the outside of the first part 61 in such a manner that the inner circumferential surface 62a of the second part 62 is in contact with the outer circumferential surface 61b of the first part 61.

The central axis of the first and second parts 61 and 62 coincides with the central axis of the outer and inner conductors 51 and 52. Accordingly, the above-mentioned axial direction corresponds to a direction of the central axis common to the outer conductor 51, the inner conductor 52, and the first and second parts 61 and 62 of the slug 60. In FIG. 4, the vertical direction corresponds to the axial direction. In FIGS. 5 and 6, the direction perpendicular to the paper corresponds to the axial direction. A direction perpendicular to the common central axis and extending outward from the central axis is defined as a radial direction.

One of the first part 61 and the second part 62 is constituted by a conductor. The other of the first part 61 and the second part 62 is constituted by a dielectric. In the first embodiment, particularly, the first part 61 is constituted by a conductor and the second part 62 is constituted by a dielectric. An example of material of the conductor constituting the first part 61 may include metal such as aluminum or the like.

The dielectric constituting the second part 62 may have, in some embodiments, a large relative dielectric constant and a small dielectric loss tangent. The relative dielectric constant of the dielectric constituting the second part 62 may be from 2 to 10000. The dielectric loss tangent of the dielectric constituting the second part 62 may be 0.02 or less.

An example of material of the dielectric constituting the second part 62 may include various types of resins, glasses, ceramics, and composites thereof. An example of ceramics used to constitute the second part 62 may include alumina, barium titanate, potassium titanate, calcium titanate, strontium titanate and magnesium titanate.

Here, assuming that the relative dielectric constant of the second part 62 is denoted by symbol εr and that the wavelength of an electromagnetic wave in air is λ0, the wavelength (effective wavelength) λg of the electromagnetic wave in the second part 62 of the slug 60 is expressed by the following Equation (1).

λg=λ0/√εr (1)

In the first embodiment, the slug 60 is configured to be a ¼ wavelength line. If the second part 62 is in full contact with the outer conductor 51, the axial length of the slug 60 may be set to λg/4 in order to configure the slug 60 as the ¼ wavelength line. However, in actuality, an air layer having a relative dielectric constant of 1 is formed between the outer circumferential surface 62b of the second part 62 and the outer conductor 51 due to a gap therebetween. Due to the existence of the air layer, in order to configure the actual slug 60 as the ¼ wavelength line, it is necessary to set the axial length of the slug 60 to be greater than λg/4. How to determine the axial length of the slug 60 in consideration of the air layer will be described in more detail later.

The slug 60 is manufactured, for example in the following manner. First, the cylindrical first part 61 and the cylindrical second part 62 are produced. For example, if a resin or a composite material of resin and ceramics is used to produce the second part 62, the second part 62 can be produced by extrusion molding or machining. Next, the first part 61 and the second part 62 are insertion-fitted and bonded together. In the case of manufacturing the slug 60 in this manner, in order to prevent the second part 62 from being cracked when the first part 61 is thermally expanded, an axially extending slit 62S may be formed in the second part 62. An example of formation of the slit 62S in the second part 62 is shown in FIG. 7.

The method of manufacturing the slug 60 is not limited to the above example. For example, the second part 62 may be formed on the outer circumferential surface 61b of the first part 61.

The slug 60 has three screw holes 60c formed to penetrate through the first and second parts 61 and 62 in the radial direction. Two of the three screw holes 60c are shown in FIG. 7. Fixing screws 65 (see FIG. 6) for fixing the slug 60 to a slide member to be described later are respectively inserted in the three screw holes 60c.

The first slug 60A and the second slug 60B are disposed at different positions in the axial direction. In the example shown in FIG. 4, the slug 60A is disposed at a position closer to the electromagnetic wave supply antenna 90 than the slug 60B.

The impedance matching device 6 further includes a driving mechanism 70 which moves the first slug 60A and the second slug 60B in the axial direction independently of each other. It is here assumed that a distance between the first slug 60A and the second slug 60B is D1 and a distance between the second slug 60B and the electromagnetic wave radiation antenna 80 is D2. The driving mechanism 70 can adjust D1 within a range of 0 to λ0/4 and can adjust D2 within a range of 0 to λ0/2.

The driving mechanism 70 includes a slug movement shaft 71A, a slide member 72A, a motor 73A and gears 74A and 75A, which are configured to move the first slug 60A in the axial direction. The driving mechanism 70 further includes a slug movement shaft 71B, a slide member 72B, a motor 73B and gears 74B and 75B, which are configured to move the second slug 60B in the axial direction. The slug movement shafts 71A and 71B extend inside the inner conductor 52 in the axial direction. The upper ends of the slug movement shafts 71A and 71B are disposed above the reflection plate 92 of the electromagnetic wave supply antenna 90. Bearings (not shown) are provided between the slug movement shafts 71A and 71B and the reflection plate 92. The lower ends of the slug movement shafts 71A and 71B may or may not be supported. If the lower ends of the slug movement shafts 71A and 71B are supported, bearings (not shown) for supporting the lower ends of the slug movement shafts 71A and 71B are installed in the bottom plate 53. Examples of the slug movement shafts 71A and 71B may include trapezoidal screw shafts.

The slide members 72A and 72B are disposed within the inner conductor 52. The slide member 72A has the same configuration as the slide member 72B. Hereinafter, in cases where the slide member 72A and the slide member 72B need not to be distinguished from each other, the slide members 72A and 72B are simply referred to as a slide member 72. As shown in FIG. 6, the slide member 72 has three projections 72a projecting in the radial direction, a screw hole 72b engaging one of the slug movement shafts 71A and 71B, and a through-hole 72c which penetrates through the slide member 72 in the axial direction and through which the other of the slug movement shafts 71A and 71B passes. The inner conductor 52 has three slit-like guide holes 52a extending in the axial direction. The three projections 72a of the slide member 72 are in contact with the slug 60 through the three guide holes 52a of the inner conductor 52. The slug 60 is fixed to the three projections 72a of the slide member 72 by fastening the three fixing screws 65 inserted in the three screw holes 60c of the slug 60. The three projections 72a of the slide member 72 have respective cutout portions formed at positions corresponding to the three screw holes 60c of the slug 60. The slug 60 and the slide member 72 are fixed in alignment such that leading ends of the fixing screws 65 are accommodated in the cutout portions.

The outer circumferential surface of the slide member 72 except the projection 72a is in contact with the inner circumferential surface of the inner conductor 52. An example of material of the slide member 72 may include a resin having excellent sliding property, such as a polyphenylene sulfide (PPS) resin.

The first slug 60A is fixed to the slide member 72A. The screw hole 72b of the slide member 72A engages the slug movement shaft 71A. The through-hole 72c of the slide member 72A passes the slug movement shaft 71A. When the slug movement shaft 71A is rotated, the slide member 72A engaging the slug movement shaft 71A and the first slug 60A fixed to the slide member 72A are moved in the axial direction.

The second slug 60B is fixed to the slide member 72B. The screw hole 72b of the slide member 72B engages the slug movement shaft 71B. The through-hole 72c of the slide member 72B passes the slug movement shaft 71A. When the slug movement shaft 71B is rotated, the slide member 72B engaging the slug movement shaft 71B and the second slug 60B fixed to the slide member 72B are moved in the axial direction.

The driving mechanism 70 further includes a housing 77 disposed on the reflection plate 92 of the electromagnetic wave supply antenna 90. The motors 73A and 73B are disposed within the housing 77. The gear 74A is fixed to the slug movement shaft 71A within the housing 77. The gear 75A is fixed to a shaft of the motor 73A and engages the gear 74A. When the motor 73A is rotated, the slug movement shaft 71A is rotated via the gears 74A and 75A. Likewise, the gear 74B is fixed to the slug movement shaft 71B within the housing 77. The gear 75B is fixed to a shaft of the motor 73B and engages the gear 74B. When the motor 73B is rotated, the slug movement shaft 71B is rotated via the gears 74B and 75B.

The driving mechanism 70 further includes two encoders 76A and 76B for detecting rotational positions of the motors 73A and 73B, respectively, and a slug controller 78 for controlling the motors 73A and 73B. Examples of the encoders 76A and 76B may include incremental type rotary encoders. The slug controller 78 controls the motors 73A and 73B based on outputs of the encoders 76A and 76B.

### <Control Unit>

The control unit 3 includes a microprocessor, a storage unit, an input unit and a display device. The storage unit stores recipes specifying a sequence and control parameters of a process of the plasma processing apparatus 100. The control unit 3 controls various components of the main body 1 and the electromagnetic wave radiation device 2 and performs predetermined plasma processing, according to a selected recipe.

### <Operation of Plasma Processing Apparatus>

Next, an operation of the plasma processing apparatus 100 will be illustrated in brief by way of an example of subjecting the substrate W to an etching process. First, the substrate W loaded into the chamber 10 by the transfer device (not shown) is mounted on the susceptor 11. Next, a plasma generation gas (for example, Ar gas) is introduced into the chamber 10 by the second gas supply unit 27 and a plurality of electromagnetic waves is radiated into the chamber 10 by the electromagnetic wave radiation device 2. The plasma generation gas is converted into plasma by the plurality of electromagnetic waves.

Next, an etching gas (for example, Cl₂ gas) as a processing gas is introduced into the chamber 10 by the first gas supply unit 24. The etching gas is excited and converted into plasma by plasma of the plasma generation gas. Using the plasma of the etching gas generated in this way, the substrate W is subjected to the etching process.

The electromagnetic waves radiated into the chamber 10 are generated in the following manner. First, in the electromagnetic wave supply source 4 of the electromagnetic wave radiation device 2, a high frequency power is output from the oscillator 32. The high frequency power is amplified by the amplifier 33 and then distributed to the plurality of power supply paths 40 by the distributor 34. The distributed high frequency power is amplified by the amplifier part 41 and then supplied to the antenna body 91 of the electromagnetic wave supply antenna 90 through the coaxial line 42, which results in generation of the electromagnetic waves propagating through the antenna body 91. In the antenna body 91, a standing wave is generated as the electromagnetic waves are reflected from the surface of the reflection portion 913. Thus, the electromagnetic waves are radiated from the antenna body 91 and are transmitted by the waveguide 50. Some of the electromagnetic waves radiated from the antenna body 91 direct to the reflection plate 92 and are reflected by the reflection plate 92. In the electromagnetic wave supply antenna 90, the standing wave is generated by some of the electromagnetic waves radiated from the antenna body 91 and the reflected waves reflected by the reflection plate 92. The electromagnetic waves transmitted by the waveguide 50 are enhanced by the generation of the standing wave.

The electromagnetic waves transmitted to the electromagnetic wave radiation antenna 80 by the waveguide 50 are radiated into the chamber 10 by the electromagnetic wave radiation antenna 80. The output impedance of the electromagnetic wave supply antenna 90 and the input impedance of the electromagnetic wave radiation antenna 80 are matched by the impedance matching device 6. The impedance matching process performed by the impedance matching device 6 is, for example, automatically performed.

### <Principle of Impedance Matching>

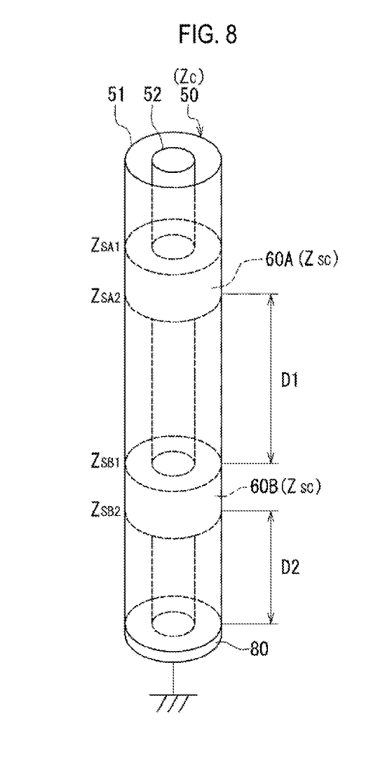

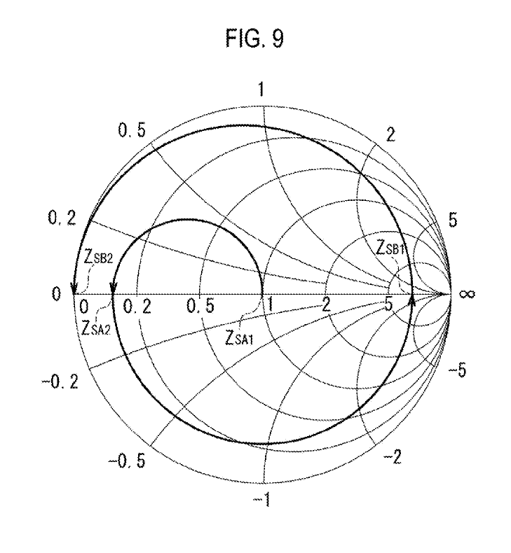

Next, the principle of the impedance matching process performed by the impedance matching device 6 will be described in detail with reference to FIGS. 8 and 9. FIG. 8 is an explanatory view illustrating impedances at a plurality of positions within the waveguide 50. FIG. 9 is an explanatory view illustrating the impedances at the plurality of positions shown in FIG. 8 on the Smith chart. In the Smith chart shown in FIG. 9, numbers on the horizontal axis represent normalized resistance and numbers on the circumference represent normalized reactance. Infinity of the normalized reactance coincides with infinity of the normalized resistance. Hereinafter, a point on the Smith chart at which the normalized resistance is 1 and the normalized reactance is 0 is referred to as a central point. The central point on the Smith chart corresponds to a point at which the absolute value of reflection coefficient is 0. In the following description, impedance at a certain position means impedance at that position which is seen from the electromagnetic wave supply source 4 side.

As shown in FIG. 8, it is assumed that characteristic impedance of the waveguide 50 is Z_{C} and characteristic impedance of each of the first slug 60A and the second slug 60B is Z_{SC}. The characteristic impedance Z_{C} of the waveguide 50 is equivalent to the output impedance of the electromagnetic wave supply source 4. The characteristic impedance Z_{SC} of each of the slugs 60A and 60B is smaller than the characteristic impedance Z_{C} of the waveguide 50.

In addition, it is assumed that impedance at a position of an end portion of the first slug 60A at the electromagnetic wave supply antenna 90 side is Z_{SA1}, impedance at a position of an end portion of the first slug 60A at the electromagnetic wave radiation antenna 80 side is Z_{SA2}, impedance at a position of an end portion of the second slug 60B at the electromagnetic wave supply antenna 90 side is Z_{SB1}, and impedance at a position of an end portion of the second slug 60B at the electromagnetic wave radiation antenna 80 side is Z_{SB2}.

Both of the slugs 60A and 60B are a ¼ wavelength line. The ¼ wavelength line allows to perform the impedance matching process on both sides of the ¼ wavelength line (both sides with the ¼ wavelength line interposed therebetween). The conditions of matching by the slugs 60A and 60B may be expressed by the following Equations (2) and (3).

Z_{SC}=√(Z_{SA1}·Z_{SA2}) (2)

Z_{SC}=√(Z_{SB1}·Z_{SB2}) (3)

In addition, on the Smith chart shown in FIG. 9, a point indicating the impedance Z_{SB1} is located at a position which is rotated by 4πD1/λ0 (radian) in the counterclockwise direction with respect to a point indicating the impedance Z_{SA2}. FIG. 9 shows an example of a case where Z_{SA1} is equivalent to Z_{C}, D1 is λ0/4, and a point indicating the impedance Z_{SB1} is at a position which is rotated by π (radian), i.e., 180°, in the counterclockwise direction with respect to a point indicating the impedance Z_{SA2}. In this example, if D1 is varied within a range of 0 to λ0/4, the imaginary part of Z_{SB1} is 0 and the real part thereof takes the maximum value when D1 is λ0/4. As a result, from Equation (3), the imaginary part of Z_{SB2} is 0 and the real part thereof takes the minimum value. If D1 is varied within a range of 0 to λ0/4, the real part of Z_{SB2} is varied within a range from the minimum value of the real part of Z_{SB2} to Z_{SA1}, i.e., Z_{C}.

On the Smith chart shown in FIG. 9, although a point indicating the input impedance of the electromagnetic wave radiation antenna 80 serving as the load (hereinafter referred to as load input impedance) is not shown, this point has the following relationship with a point indicating the impedance Z_{SB2}. That is, the point indicating the load input impedance is at a position which is rotated by 4πD2/λ0 (radian) in the counterclockwise direction with respect to the point indicating the impedance Z_{SB2}.

The impedance matching process performed by the impedance matching device 6 is to convert the load input impedance into Z_{SA1} to make Z_{SA1} equivalent to Z_{C} based on the above-described relationship between the plurality of points. This means bringing the point indicating the impedance Z_{SA1} to the central point on the Smith chart, as shown in FIG. 9.

A range of the load input impedance which can be matched by the impedance matching device 6 can be found in the following manner. First, on the Smith chart, the point indicating the impedance Z_{SA1} is placed at the central point, as shown in FIG. 9. Next, Equation (2) is used to find the impedances Z_{SA1} and Z_{SA2}. Next, the impedances Z_{SA2} and Z_{SB1} are found with D1 set to λ0/4. Next, Equation (3) is used to find the impedances Z_{SB1} and Z_{SB2}. Arrows in FIG. 9 indicate finding the impedances Z_{SA2}, Z_{SB1} and Z_{SB2} in turn from the impedance Z_{SA1} in this way. The range of the matchable load input impedance is a range enclosed by a circle passing through the point indicating the impedance Z_{SB2} with the central point as the center on the Smith chart. Hereinafter, this circle is referred to as a boundary circle.

If the point indicating the load input impedance lies on the boundary circle, by adjusting D2, the load input impedance is converted into Z_{SB2} which is then converted into Z_{SB1}, Z_{SA2} and Z_{SB1} in turn, making Z_{SA1} equivalent to Z_{C}.

If the point indicating the load input impedance lies inside the boundary circle, by adjusting D1 and changing Z_{SB2} into a value into which the load input impedance can be converted, that is, a value on the circle passing through the point indicating the load input impedance with the central point as the center on the Smith chart, Z_{SB1} can be made equivalent to Z_{C}, in a manner similar to the above description.

The above boundary circle is constant in terms of an absolute value |Γ| of the reflection coefficient Γ. Here, a voltage standing wave ratio (VSWR) is expressed by the following Equation (4).

VSWR=(1+|Γ|)/(1−|Γ|) (4)

The boundary circle is also constant in terms of VSWR. As can be understood from Equation (4), VSWR is 1 when |Γ| is 0, increases as |Γ| increases, and becomes infinity when |Γ| is 1. A larger VSWR indicating the boundary circle provides a wider range of the matchable load input impedance.

### <Expansion of Matchable Range>

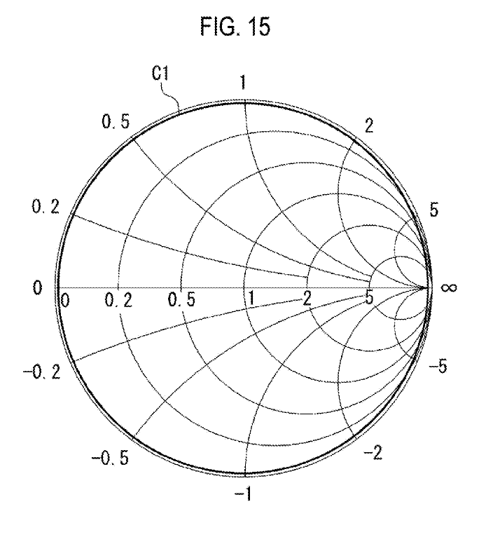

The slug 60 according to the first embodiment allows the range of the matchable input impedance to be expanded, in comparison to a slug entirely constituted by dielectric according to a comparative example which will be described later with reference to FIG. 15. The reason for this will be described in detail below. The overall shape of the slug of the comparative example is the same as that of the slug 60. The dielectric constituting the slug of the comparative example is the same as the dielectric constituting the second part 62 of the slug 60.

First, the slug 60 can be regarded as a transverse electromagnetic (TEM) wave transmission line. Accordingly, if a transmission loss in the slug 60 can be negligible, the characteristic impedance Z_{SC} of the slug 60 can be expressed by the following Equation (5), like the characteristic impedance of the TEM wave transmission line. Similarly, the characteristic impedance Z_{SC} of the slug of the comparative example can be also expressed by Equation (5). In Equation (5), L denotes inductance per unit length of the line (slug) and C denotes capacitance per unit length of the line (slug).

Z_{SC}=√(L/C) (5)

The slug of the comparative example is interposed between two conductors, i.e., the inner conductor 52 and the outer conductor 51 of the waveguide 50. Capacitance C of the slug of the comparative example depends on a slug thickness in the radial direction. On the other hand, in the slug 60, the first part 61 adjacent to the inner conductor 52 is constituted by a conductor and the second part 62 made of dielectric is interposed between two conductors, i.e., the first part 61 and the outer conductor 51. Capacitance C of the slug 60 depends on the thickness of the second part 62 in the radial direction. The thickness of the second part 62 in the radial direction is smaller than the thickness of the slug of the comparative example in the radial direction. Accordingly, the capacitance C of the slug 60 is higher than the capacitance C of the slug of the comparative example. Accordingly, from Equation (5), the characteristic impedance Z_{SC} of the slug 60 is lower than the characteristic impedance Z_{SC} of the slug of the comparative example.

When Z_{SA1} is made equivalent to Z_{C}, from Equation (2), Z_{SA2} decreases as Z_{SC} decreases. When D1 is set to λ0/4 and Z_{SB1} is obtained from Z_{SA2} in the manner shown in FIG. 9, Z_{SB1} increases as Z_{SA2} decreases. Accordingly, as Z_{SC} decreases, since Z_{SC} in Equation (3) decreases and Z_{SB1} increases, Z_{SB2} decreases. This means that the boundary circle becomes larger.

From the above description, the slug 60 according to the first embodiment can provide the characteristic impedance Z_{SC} lower than that of the slug of the comparative example, which is entirely constituted by dielectric. As a result, it is possible to expand the range of the matchable load input impedance (the boundary circle).

As a ratio of the thickness of the second part 62 in the radial direction to the thickness of the slug 60 in the radial direction (hereinafter simply referred to as a thickness ratio of the second part 62) decreases, the characteristic impedance Z_{SC} of the slug 60 can decrease. From this point of view, the thickness ratio of the second part 62 may be smaller in some embodiments. In order that the above-described effects of the slug 60 can be remarkably exhibited, the thickness ratio of the second part 62 may be 50% or less in some embodiments, and 25% or less in some other embodiments.

On the other hand, if the thickness ratio of the second part 62 is too small, there may rise problems in that it is difficult to form the second part 62 with high precision, in that the first part 61 and the inner conductor 52 are easily short-circuited, and in that an air layer which will be described later shows remarkable effects. In order to avoid these problems, the thickness ratio of the second part 62 may be 5% or more in some embodiments.

### <Length of Slug 60 in Consideration of Air Layer>

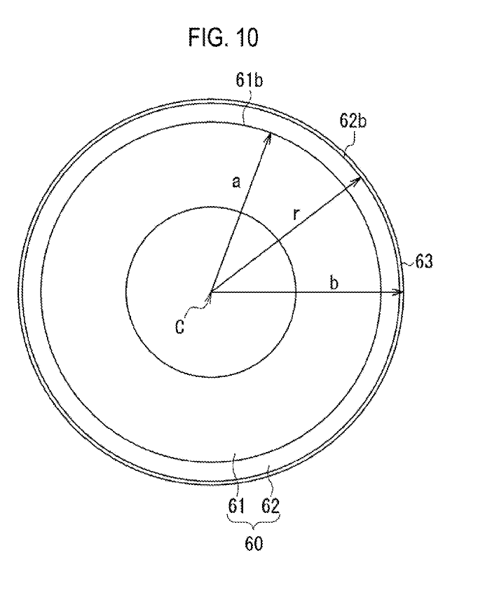

Next, how to determine a length of the slug 60 in the axial direction in consideration of an air layer will be described in detail. FIG. 10 is a sectional view illustrating the slug 60 and an air layer 63. As shown in FIG. 10, the air layer 63 exists between the outer circumferential surface 62b of the second part 62 of the slug 60 and the outer conductor 51 (see FIG. 6). The relative dielectric constant of the air layer 63 is 1.

Here, in the section shown in FIG. 10, a distance from the central axis C common to the first and second parts 61 and 62 of the slug 60 to the outer circumferential surface 61b of the first part 61 is defined as the radius of the outer circumferential surface 61b of the first part 61, which is denoted by symbol a. In addition, in the section shown in FIG. 10, a distance from the central axis C to the outer conductor 51 is denoted by symbol b. In addition, in the section shown in FIG. 10, a distance from the central axis C to the outer circumferential surface 62b of the second part 62 is defined as the radius of the outer circumferential surface 62b of the second part 62, which is denoted by symbol r. The thickness of the air layer 63 in the radial direction is b−r.

Next, the characteristic impedance Z_{SC} of the slug 60 in a case where the air layer 63 is regarded as a portion of the slug 60 is obtained. Z_{SC} is expressed by the above Equation (5). Here, C and L are expressed by the following Equations (6) and (7). In these Equations (6) and (7), ε0 represents a vacuum dielectric constant and μ0 represents a vacuum permeability.

C[F/m]=2πε0/{(1/εr)·ln(r/a)+ln(b/r)} (6)

L[H]={μ0 ln(b/a)}/2π (7)

From Equations (5), (6) and (7), the characteristic impedance Z_{SC} of the slug 60 is expressed by the following Equation (8).

Z_{SC}=60√[ln(b/a)·{(1/εr)·ln(r/a)+ln(b/r)}] (8)

Next, an effective relative dielectric constant εr* of the second part 62 in consideration of the air layer 63 is defined as the following Equation (9). In Equation (9), Z_{SO} represents a characteristic impedance of a virtual slug under the presumption that a space between the first part 61 and the outer conductor 51 is the vacuum, and is expressed by the following Equation (10).

εr*=(Z_{S0}/Z_{SC})2 (9)

Z_{S0}=60 ln(b/a) (10)

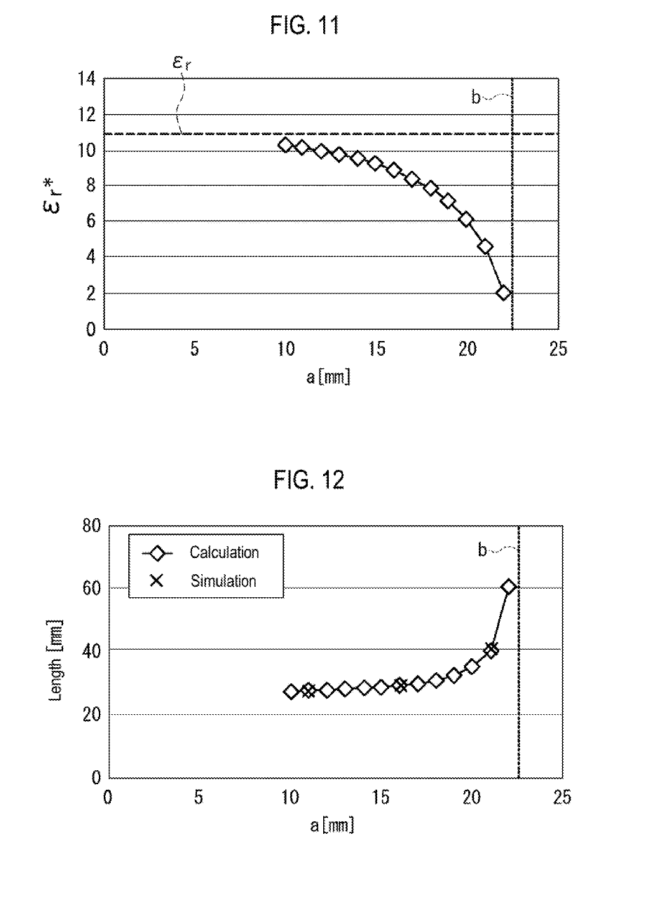

Next, a result of calculation on εr* with b set to 22.5 mm, r set to 22.28 mm, and μr set to 11 while a value of the radius a is varied is shown in FIG. 11. FIG. 11 is a characteristic diagram illustrating a relationship between a value of the radius a and εr*. In FIG. 11, the horizontal axis represents a value of the radius a and the vertical axis represents εr*. As shown in FIG. 11, as the value of the radius a increases and the thickness (r−a) of the second part 62 in the radial direction decreases, the effective relative dielectric constant εr* decreases. It is believed that this is because the effect of the air layer 63 whose relative dielectric constant is 1 is actualized as the thickness of the second part 62 decreases.

Next, in addition to the above conditions, under conditions where the frequency of an electromagnetic wave in air is 860 MHz, a relationship between a value of the radius a and an optimal length of the slug 60 was obtained by calculation and simulation. A result thereof is shown in FIG. 12. FIG. 12 is a characteristic diagram illustrating a relationship between a value of the radius a and an optimal length of the slug 60. In FIG. 12, the horizontal axis represents a value of the radius a and the vertical axis represents an optimal length of the slug 60. The optimal length of the slug 60 refers to a length of the slug 60 in the axial direction when the slug 60 acts as a ¼ wavelength line. As shown in FIG. 12, as a increases and the thickness (r−a) of the second part 62 in the radial direction decreases, the optimal length of the slug 60 increases. This is because the effective relative dielectric constant εr* decreases as the value of the radius a increases, as shown in FIG. 11.

In addition, even when the slit 62S is formed in the second part 62 as shown in FIG. 7, it was confirmed through simulation that the effective relative dielectric constant εr* of the slug 60 was little affected.

### <Characteristic Impedance of Slug 60 and VSWR>

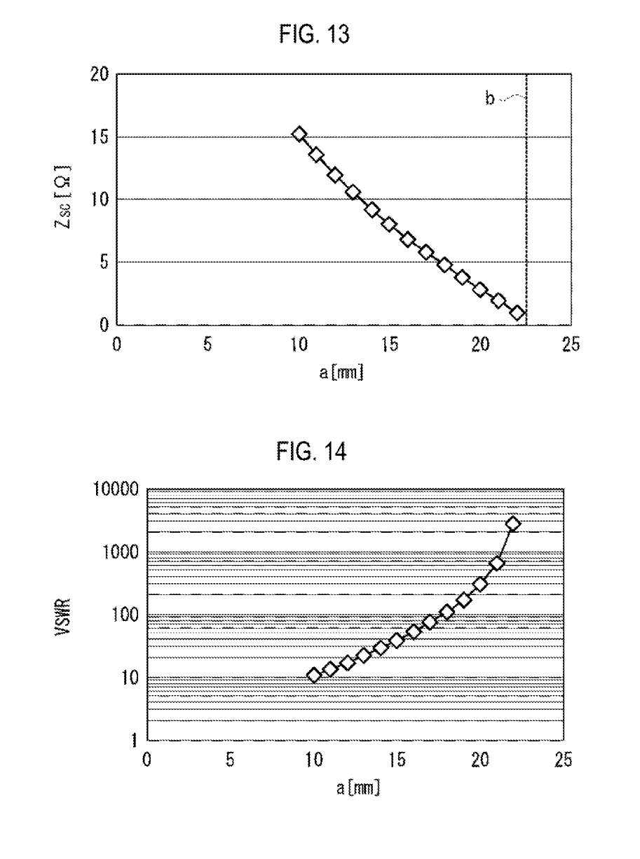

Next, when the length of the slug 60 was set to the optimal length shown in FIG. 12, a relationship between a value of the radius a and the characteristic impedance Z_{SC} of the slug 60 and a relationship between a value of the radius a and VSWR indicating a boundary circle were obtained. FIG. 13 is a characteristic diagram illustrating a relationship between a value of the radius a and the characteristic impedance Z_{SC} of the slug 60. In FIG. 13, the horizontal axis represents a value of the radius a and the vertical axis represents Z_{SC}. FIG. 14 is a characteristic diagram illustrating a relationship between a value of the radius a and a value of the VSWR indicating a boundary circle. In FIG. 14, the horizontal axis represents a value of the radius and the vertical axis represents VSWR.

As shown in FIGS. 13 and 14, as the radius a increases, the characteristic impedance Z_{SC} decreases and the VSWR indicating the boundary circle increases. Accordingly, as the radius a increases, a range of matchable load input impedance can be expanded.

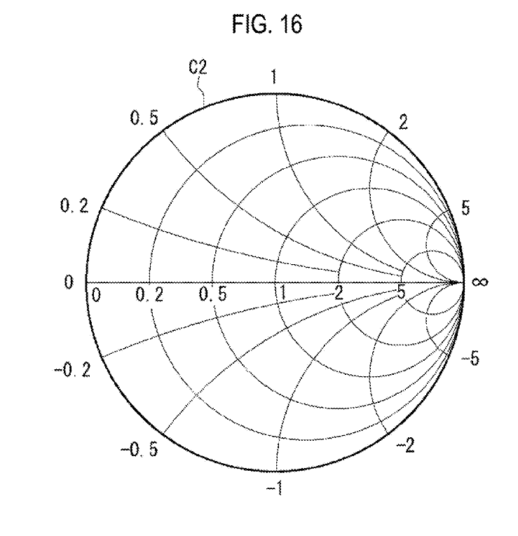

Next, one example of results of simulation through which VSWR indicating a boundary circle is obtained for a case where the slug of the comparative example is used and a case where the slug 60 is used is shown in FIGS. 15 and 16. The slug of the comparative example is entirely constituted by alumina as a dielectric. FIG. 15 illustrates a boundary circle C1 in a case where the slug of the comparative example is used. VSWR indicating this boundary circle C1 is 9.6.

FIG. 16 illustrates a boundary circle C2 in a case where the slug 60 is used. In simulation, a value of 2.49Ω was obtained as the characteristic impedance Z_{SC} of the slug 60, and in this case, VSWR indicating the boundary circle C2 was 399. In this way, with the slug 60 according to the first embodiment, it is possible to significantly expand the range of matchable load input impedance (the boundary circle C2) in comparison with the slug of the comparative example which is entirely constituted by a dielectric.

### <Other Effects of Slug 60>

Next, other effects of the slug 60 will be described. In the driving mechanism 70 according to the first embodiment, the slide member 72 is installed inside the inner conductor 52 and the slug 60 is fixed to the projections 72a of the slide member 72. The guide holes 52a through which the projections 72a pass are formed in the inner conductor 52. Conventionally, in a case of driving the slug of the comparative example entirely constituted by a dielectric by means of the driving mechanism 70 having this structure, an electric field is likely to concentrate on the vicinity of the guide holes 52a, which results in leakage of the electric field from the slug of the comparative example to the inner conductor 52.

For the configuration where the slug of the comparative example is provided instead of the slug 60, an electromagnetic simulation showed a result that an electric field on the surfaces of the projections 72a increased in both regions of the fixing screw 65. This indicates that the electric field leaks from the slug of the comparative example to the inner conductor 52 in the vicinity of the guide holes 52a. In addition, the electric field on the surface of the projections 72a was maximized at a position distanced by about 6 mm from the center of the fixing screw 65. The electric field at this position was about 9×10⁴ V/m.

On the contrary, according to the slug 60 of the first embodiment, the first part 61 constituted by a conductor is interposed between the second part 62 constituted by a dielectric and the inner conductor 52. Therefore, according to the first embodiment, the first part 61 acts as a shield and it is possible to suppress the electric field from leaking from the slug 60. i.e., the second part 62, to the inner conductor 52.

For the configuration of the first embodiment, an electromagnetic simulation showed a result that an electric field on the surfaces of the projections 72a was about 0 in both regions of the fixing screw 65. This indicates that the slug 60 according to the first embodiment can suppress the electric field from leaking from the slug 60 to the inner conductor 52.

### Second Embodiment

Next, a second embodiment of the present disclosure will be described. An impedance matching device, an electromagnetic wave transmission device, an electromagnetic wave radiation device and a plasma processing apparatus according to the second embodiment include a slug 160 according to the second embodiment, instead of the slug 60 according to the first embodiment.

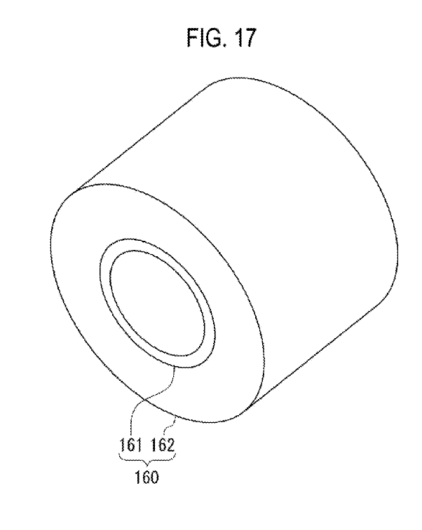

FIG. 17 is a perspective view of the slug 160 according to the second embodiment. As shown in FIG. 17, the slug 160 according to the second embodiment includes a cylindrical first part 161 and a cylindrical second part 162 which are coupled to each other. Each of the first part 161 and the second part 162 has an inner circumferential surface facing the inner conductor 52 (see FIG. 4) and an outer circumferential surface facing the outer conductor 51 (see FIG. 4). The second part 162 is disposed in the outside of the first part 161 in such a manner that the inner circumferential surface of the second part 162 is in contact with the outer circumferential surface of the first part 161. In the slug 160 according to the second embodiment, as opposed to the slug 60 according to the first embodiment, the first part 161 is constituted by a dielectric and the second part 162 is constituted by a conductor.

The dielectric constituting the first part 161 is made of the same material as the dielectric constituting the second part 62 of the slug 60 according to the first embodiment. The conductor constituting the second part 162 is made of the same material as the conductor constituting the first part 61 of the slug 60 according to the first embodiment. In some embodiments, a range of a ratio of thickness of the first part 161 in the radial direction to the thickness of the slug 160 in the radial direction may be the same as the range of the thickness ratio of the second part 62 in the slug 60 according to the first embodiment.

According to the slug 160 of the second embodiment, like the slug 60 according to the first embodiment, the characteristic impedance Z_{SC} can be reduced in comparison with the slug of the comparative example entirely constituted by a dielectric, which results in expansion of a matchable load input impedance range (boundary circle).

When the slug 160 according to the second embodiment is in combination with a driving mechanism having a structure where a slide member is installed inside the inner conductor 52, an electric field is likely to leak from the first part 161 to the inner conductor 52 in the vicinity of the guide holes 52a of the inner conductor 52. Therefore, the slug 160 according to the second embodiment is suitable to be used in combination with a driving mechanism having a structure where the slide member is installed outside the outer conductor 51. In this case, a slit-like guide hole extending in the axial direction is formed in the outer conductor 51. However, according to the slug 160 of the second embodiment, the second part 162 constituted by a conductor acts as a shield and it is possible to suppress an electric field from leaking from the first part 161 to the outer conductor 51 in the vicinity of the guide hole.

The present disclosure is not limited to the above embodiments but various modifications may be made. For example, the configuration of the main body 1 of the plasma processing apparatus 100, the number of electromagnetic wave transmission devices 5 and the number of the electromagnetic wave radiation antennas 80 are not limited to the example shown in the first embodiment but may be arbitrarily selected, as long as the requirements of the claims are satisfied. In addition, application of the impedance matching slug, the impedance matching device and the electromagnetic wave transmission device of the present disclosure are not limited to the plasma processing apparatus, but they may be applied to a generalized system for transmitting an electromagnetic wave supplied from an electromagnetic wave supply source to a load through a waveguide.

According to the present disclosure in some embodiments, the impedance matching slug includes the first part and the second part, one of the first part and the second part is constituted by a conductor, and the other of the first part and the second part is constituted by a dielectric. In the impedance matching slug configured in this manner, it is possible to decrease the characteristic impedance in comparison with a slug entirely constituted by a dielectric. Thus, according to the impedance matching slug of the present disclosure, it is possible to expand the range of the matchable load input impedance in comparison with the slug entirely constituted by the dielectric.

In addition, all of the impedance matching device, the electromagnetic wave transmission device, the electromagnetic wave radiation device and the plasma processing apparatus of the present disclosure include the first slug and the second slug having the same configuration as the impedance matching slug of the present disclosure. Thus, according to these devices and apparatus of the present disclosure, it is possible to expand the range of the matchable load input impedance by using the first and second slugs in comparison with the case using two slugs entirely constituted by the dielectric.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An impedance matching slug that performs an impedance matching process between an output impedance of an electromagnetic wave supply source and an input impedance of a load, in a waveguide for transmitting an electromagnetic wave supplied from the electromagnetic wave supply source to the load, the waveguide including a cylindrical outer conductor and an inner conductor which is coaxial to the outer conductor and is installed inside the outer conductor, and the impedance matching slug being axially movably interposed between the outer conductor and the inner conductor, the impedance matching slug comprising:
a cylindrical first part and a cylindrical second part which are coupled to each other,
wherein each of the first part and the second part has an inner circumferential surface facing the inner conductor and an outer circumferential surface facing the outer conductor,
wherein the second part is disposed in the outside of the first part in such a manner that the inner circumferential surface of the second part is in contact with the outer circumferential surface of the first part,
wherein one of the first part and the second part is constituted by a conductor, and
wherein the other of the first part and the second part is constituted by a dielectric.

2. The impedance matching slug of claim 1, wherein the first part is constituted by a conductor and the second part is constituted by a dielectric.

3. An impedance matching device that performs an impedance matching process between an output impedance of an electromagnetic wave supply source and an input impedance of a load, in a waveguide for transmitting an electromagnetic wave supplied from the electromagnetic wave supply source to the load, the waveguide including a cylindrical outer conductor and an inner conductor which is coaxial to the outer conductor and is installed inside the outer conductor, the impedance matching device comprising:
a first slug and a second slug which are axially movably interposed between the outer conductor and the inner conductor; and
a driving mechanism that moves the first slug and the second slug in an axial direction, independently of each other,
wherein each of the first slug and the second slug includes a cylindrical first part and a cylindrical second part which are coupled to each other,
wherein each of the first part and the second part has an inner circumferential surface facing the inner conductor and an outer circumferential surface facing the outer conductor,
wherein the second part is disposed in the outside of the first part in such a manner that the inner circumferential surface of the second part is in contact with the outer circumferential surface of the first part,
wherein one of the first part and the second part is constituted by a conductor, and
wherein the other of the first part and the second part is constituted by a dielectric.

4. An electromagnetic wave transmission device comprising:
a waveguide that transmits an electromagnetic wave supplied from an electromagnetic wave supply source to a load; and
an impedance matching device that performs an impedance matching process between an output impedance of the electromagnetic wave supply source and an input impedance of the load,
wherein the waveguide includes a cylindrical outer conductor and an inner conductor which is coaxial to the outer conductor and is installed inside the outer conductor,
wherein the impedance matching device includes:
a first slug and a second slug which are axially movably interposed between the outer conductor and the inner conductor; and
a driving mechanism that moves the first slug and the second slug in an axial direction, independently of each other,
wherein each of the first slug and the second slug includes a cylindrical first part and a cylindrical second part which are coupled to each other,
wherein each of the first part and the second part has an inner circumferential surface facing the inner conductor and an outer circumferential surface facing the outer conductor,
wherein the second part is disposed in the outside of the first part in such a manner that the inner circumferential surface of the second part is in contact with the outer circumferential surface of the first part,
wherein one of the first part and the second part is constituted by a conductor, and
wherein the other of the first part and the second part is constituted by a dielectric.

5. An electromagnetic wave radiation device comprising:
a waveguide that transmits an electromagnetic wave;
an electromagnetic wave supply source that supplies the electromagnetic wave to the waveguide;
an electromagnetic wave radiation antenna that radiates the electromagnetic wave transmitted by the waveguide; and
an impedance matching device that performs an impedance matching process between an output impedance of the electromagnetic wave supply source and an input impedance of the electromagnetic wave radiation antenna,
wherein the waveguide includes a cylindrical outer conductor and an inner conductor which is coaxial to the outer conductor and is installed inside the outer conductor,
wherein the impedance matching device includes:
a first slug and a second slug which are axially movably interposed between the outer conductor and the inner conductor; and
a driving mechanism that moves the first slug and the second slug in an axial direction, independently of each other,
wherein each of the first slug and the second slug includes a cylindrical first part and a cylindrical second part which are coupled to each other,
wherein each of the first part and the second part has an inner circumferential surface facing the inner conductor and an outer circumferential surface facing the outer conductor,
wherein the second part is disposed in the outside of the first part in such a manner that the inner circumferential surface of the second part is in contact with the outer circumferential surface of the first part,
wherein one of the first part and the second part is constituted by a conductor, and
wherein the other of the first part and the second part is constituted by a dielectric.

6. The electromagnetic wave radiation device of claim 5, wherein the electromagnetic wave supply source includes: an electromagnetic wave supply antenna that generates the electromagnetic wave supplied to the waveguide; and a power feeding part that feeds an electric power for generating the electromagnetic wave to the electromagnetic wave supply antenna.

7. A plasma processing apparatus comprising:
a chamber that accommodates a substrate to be processed;
a gas supply device that supplies a gas into the chamber; and
an electromagnetic wave radiation device of claim 5,
wherein the electromagnetic wave radiation antenna of the electromagnetic wave radiation device radiates an electromagnetic wave into the chamber, and
wherein the gas supplied into the chamber is converted into plasma by the electromagnetic wave radiated into the chamber and the substrate is processed using the plasma.

8. A plasma processing apparatus comprising:
a chamber that accommodates a substrate to be processed;
a gas supply device that supplies a gas into the chamber; and
an electromagnetic wave radiation device of claim 6,
wherein the electromagnetic wave radiation antenna of the electromagnetic wave radiation device radiates an electromagnetic wave into the chamber, and
wherein the gas supplied into the chamber is converted into plasma by the electromagnetic wave radiated into the chamber and the substrate is processed using the plasma.
